(19) United States
(12) Patent Application Publication
(10) Pub. No.: US 2013/0176675 A1
(43) Pub. Date: Jul. 11, 2013

(54) APPARATUS AND METHOD FOR COOLING A SUBSTANTIALLY CLOSED SPACE

(71) Applicant: Thomas Ferdinand Willem Hundertmark, Rijswijk (NL)

(72) Inventor: Thomas Ferdinand Willem Hundertmark, Rijswijk (NL)

(73) Assignee: DEERNS RAADGEVENDE INGENIEURS B.V., Rijswijk (NL)

(21) Appl. No.: 13/810,779

(22) PCT Filed: Jul. 22, 2011
(86) PCT No.: PCT/NL2011/050535

§ 371 Date: Mar. 28, 2013

(30) Foreign Application Priority Data
Jul. 23, 2010 (NL) 2005138

(51) Int. Cl. H05K 7/20; F24F 3/14

(52) U.S. Cl. CPC H05K 7/20145; H05K 7/202; H05K 7/20209; F24F 3/14
USPC 361/679.31; 165/280; 165/297; 165/223

(57) ABSTRACT

An apparatus for cooling a substantially closed space with recirculation air having at least one cooling unit which includes a heat exchanger with a primary set of ducts and a secondary set of ducts, each set of ducts having an in- and outlet. The unit includes a controller to control an operation of the unit, and a sensor to provide a sensor signal representative of a parameter of the unit. The controller is arranged to derive a control signal from the sensor signal, whereby the unit includes a control signal output for outputting the control signal to another unit and a control signal input for receiving a control signal from another unit, the controller being arranged to control the operation of the unit in response to the control signal and the control signal from another unit as received at the control signal input.

### CROSS-REFERENCE TO RELATED APPLICATIONS

This application is the National Stage of International Application No. PCT/NL2011/050535, filed Jul. 22, 2011, which claims the benefit of Netherlands Application No. 2005138, filed Jul. 23, 2010, the contents of which is incorporated by reference herein.

### FIELD OF THE INVENTION

The invention relates to an apparatus and method for cooling a substantially closed space, in particular a data centre, with recirculation air, as well as to such a datacenter. Furthermore, the invention relates to such datacenter.

### BACKGROUND OF THE INVENTION

WO2009/108043 discloses a cooling of a datacenter. A first air stream is guided through data processing equipment of the datacenter. The air stream is guided to a plate heat exchanger where it is cooled by a second air stream comprising ambient air. Then, the first air stream is guided back to the datacenter for cooling of the data processing equipment. The second air stream a separated from the first air stream.

In applications such as datacenters or cooling of other substantially closed spaces, use may be made of a plurality of cooling units each comprising a heat exchangers (such as the recirculation heat exchanger as described in WO2009/108043) all units being in connection with the same space. Thereby, a total cooling capacity may be increased, and/or redundancy provided in case of one the units, or associated equipment malfunctions, is subjected to maintenance or repair, etc.

A problem of such known cooling is that energy efficiency as obtained in operation may be sub-optimal. In the described units each comprising a heat exchanger, energy consumption is to a substantial amount determined by a power consumption of air displacement devices such as ventilators. In a configuration as described, a plurality of air displacement devices may be provided: each heat exchanger may be provided with two or more air displacement devices, namely at least one for each of the air streams. The known control of each of the air displacement devices, e.g. in response to a signal provided by its temperature or pressure sensor, may result in a sub optimum situation.

In the known configurations, each unit (or possibly even each air displacement device) and other actuators, such as additional cooling devices, humidifiers, de-humidifiers, etc, is provided with its own control. At the same time, many different variations in variables (such as variations in power dissipation by individual servers, wear and aging of individual components, etc, may take place. From a system perspective, the individual control may not be able to adequately handle such situations and may not be able to provide adequate system performance. Such below adequate performance may result in unnecessary consumption of energy and/or result in the cooling system not achieving a required performance.

Furthermore a sub optimal dynamic response of actuators in the apparatus may occur in case of changes in the overall configuration. Such changes may occur as a result of many causes, such as by addition, removal or taking out of service of parts or components or data processing equipment, pressure, air flow and/or temperature differences by opening or closing of a door, changes in a dissipation or dissipation distribution of the datacenter, changes in environmental temperature, errors by maintenance staff (such as forgetting to close an opening in a computer rack after removal of a unit from the rack, forgetting to close a door, a window, service opening, removal or placement of data processing equipment, or others). This may result in low performance and therefore in unnecessary consumption of energy and/or the cooling system not achieving a required performance.

Still further, a load distribution between air displacement devices of the servers themselves and air displacement devices of the heat exchanger may be sub optimal. Again, this may result in low performance and therefore in unnecessary consumption of energy and/or the cooling system not achieving a required performance.

The invention intends to solve or at least reduce an effect of one or more of the above problems.

### SUMMARY OF THE INVENTION

In order to reach this goal, the apparatus according to the invention comprising at least one unit for cooling, the unit comprising a heat exchanger with a primary set of ducts and a secondary set of ducts, each set of ducts having an in- and outlet, wherein the primary in- and outlet ducts are connected to an outside environment to form a first recirculation path, and the secondary in- and outlet ducts are connected to the substantially closed space to form a second recirculation path, the unit comprising a controller to control an operation thereof, and a sensor to provide a sensor signal representative of a parameter of the unit, the controller being arranged to derive a control signal from the sensor signal, whereby the unit comprises a control signal output for outputting the control signal to another unit and a control signal input for receiving a control signal from another unit, the controller being arranged to control the operation of the unit in response to the control signal and the control signal from another unit as received at the control signal input.

Thereby, a redundant operation may be provided: in case one of the sensors malfunctions and thereby does not provide a sensor signal, in case its connection (e.g. cabling) is interrupted, or in case the sensor or unit is switched off, its signal can be discarded. Hence, normal operation of the units may continue even if for example a sensor or its cabling is broken. Furthermore, the cooling units (also referred to in this document as “units”) are configured to operate in parallel to each other, as all units draw air from the substantially closed space and provide cooled air back to the same space. By providing all units with the same control signals, all units operate from a same control value and therefore operate in regard of the measured parameter at a substantially same setting. Thereby, an efficient and stable operation may be provided as “competition” between the units and other such effects may be avoided. Furthermore, an energy efficient operation may be provided, as all units may operate at a same setting, hence exhibit a same level of energy consumption, thereby avoiding that one unit operates at a peak level at a high energy consumption, while others operate at a lower (e.g. more efficient) level. In particular in an apparatus having two or more units, system performance and load distribution between air displacement devices may be improved.

The control signal input and output of the unit(s) may comprise any suitable input respectively output: for analogue signal transmission (single sided or balanced, baseband or using any type of signal modulation on a carrier wave, etc) or digital signal transmission (point to point or data bus, thereby using any suitable type of communication protocol). The control signal may hence comprise an analogue signal and/or a digital signal. The operation that is controlled may comprise any kind of operation of the unit such as air displacement device operation, valves, etc. The control signal may be in any relation to the sensor signal, it may for example be an amplified or buffered sensor signal, a linearized sensor signal, express a deviation of the measured sensor signal from a nominal (desired) sensor signal value, comprise a filtered sensor signal, express a level of a to be taken action such as a desired operating level of an air displacement device, etc, or any other action, as well as combinations of the above).

In an embodiment, the controller of the unit comprises a maximum determiner that is arranged to determine a maximum from the control signal and the control signal from another unit as received at the control signal input. The maximum may be a highest value, lowest value, or any other extreme, etc. Thereby, each unit determines a maximum of the control signals it obtains. As a result, a redundant operation is provided by simple means (namely a selection of the sensor/control signal having the most relevant and/or most demanding value). Furthermore, dysfunctional sensors, of which the sensor signal is for example zero, may easily be discarded. Still further, it is ensured that a summed operation of the units together (e.g. their cooling power) is sufficient to be able to cope with the maximum signal measured, i.e. the most demanding condition occurring at that moment in time.

Preferably, the sensors are located such that each sensor is positioned to measure the parameter at a location representative for the unit in question. More than one sensor per unit may be installed in order to further increase a resilience and quality of the control signals from the sensors. In an embodiment, the space is divided into a cold section and a warm section by substantially air tight dividing means (such as frames, racks or cabinets in which electronics (e.g. servers) can be mounted), the cold section being connected to the secondary outlet duct, the warm section being connected to the secondary inlet duct, the dividing means being provided with openings at a location of a heat source (such as the electronics), the sensor comprises a pressure difference sensor, the pressure difference sensor being configured to measure a pressure difference between the cold section and the warm section. Thereby, the controller being configured to drive a secondary air displacement device comprised in the unit in response to a maximum of a pressure difference control signal derived from the pressure difference measured by the pressure difference sensor of the unit and at least one pressure difference control signal from at least one other unit as received at the control signal input. Hence, in particular in an apparatus comprising at least two cooling units, system performance, dynamic response and load distribution may be improved. In addition to the above mentioned advantages, local pressure differences (due to for example different servers taking different amounts of air), which would otherwise result in different operating conditions of the units, may hence be discarded, and all units may be kept at a same level. Preferably, the controller comprises a dual control loop architecture, whereby an inner air displacement device control loop comprises an inner loop pressure difference sensor over the secondary ducts and an inner air displacement device controller, and the outer air displacement device control loop comprises the pressure difference sensor and an outer air displacement device controller. System performance and load distribution as referred to above may benefit. Variables such as variation in ventilators, lifespan and clogging of a filter etc. may be compensated by the inner loop (which may thereto be provided with a proportional integrative controller), while the outer loop (which may thereto be provided with a proportional controller) maintains the pressure difference within a specified range. This may reliably be implemented by an output of the outer air displacement device controller of the unit being connected to the maximum determiner, an output of the maximum determiner being provided as a set point to the inner air displacement device controller.

In an embodiment, each unit comprises a secondary bypass damper to bypass the space. Thereby, additional circulation may be obtained in case the unit would run out of its optimum operating condition. In case for example the air temperature drawn into the heat exchanger by the secondary inlet duct would have a to high temperature (which would result in mal-performance of the unit when operating in higher load conditions), additional colder air may be added via the bypass damper so as to lower the air temperature. As another example, in case the total amount of air taken by the electronics of the datacenter or others would be low, additional circulation may be generated by opening the damper in order to create an airflow within a control range of the air displacement device. Dynamic response and load distribution between units may benefit. The bypass damper may be provided in combination with the described input and outputs for communicating control signals between units, and its optional further embodiments, however may also be applied as such, i.e. without with the described input and outputs for communicating control signals between units.

In an embodiment, in order to control the bypass damper, the unit comprises a secondary temperature sensor and a secondary temperature controller configured to provide a temperature control signal representative of an air temperature in the secondary inlet duct, a pressure controller to derive a pressure difference control signal from the pressure difference between cold section and the warm section as sensed by the pressure difference sensor, and a secondary bypass controller configured to control the secondary bypass damper, wherein the secondary bypass controller is configured to drive the secondary bypass damper in dependency on a highest of the temperature control signal and the pressure difference control signal. Pressure difference control dominates at a high pressure difference, which occurs when the air displacement device is not able to transport a sufficiently high volume of air. Open the bypass damper will enable to increase air volume. Temperature control dominates for example when a hotspot occurs. Opening the damper allows cold air to flow in the plenum thereby reducing an air temperature of the hot air. Thereby, the secondary bypass controller is configured to allow the bypass damper to open only when a secondary side heat exchanger pressure difference sensor indicates that a pressure difference over the secondary side of the heat exchanger exceeds below a predetermined minimum pressure difference level. A low pressure difference over the secondary side of the heat exchanger implies a low secondary circulation, which—given the described control of the secondary air displacement device—implies a high pressure difference between the cold section and warm section. As the bypass damper control is activated only from this condition, opening of the bypass damper in other situations where it may not be desirable, may be avoided. In a still further embodiment, the secondary bypass controller is further be configured to open the bypass damper when the secondary side heat exchanger pressure difference sensor indicates that the pressure difference over the secondary side of the heat exchanger exceeds above a predetermined maximum pressure difference level, so as to avoid damage due to overpressure. It will be understood that the bypass damper and its control as described in this paragraph and further detailed in this document may but not necessarily needs to be combined with the other features as described above. Rather, it may also be provided in any other apparatus for cooling a substantially closed space.

In an embodiment, the unit comprises a primary air displacement device arranged in one of the primary inlet duct and the primary outlet duct, a secondary temperature sensor arranged to measure a temperature of the air in the secondary outlet duct, and a primary air displacement device controller configured to control the primary air displacement device in dependency of a temperature as measured by the secondary side temperature sensor. Thereby, a primary flow of air may be controlled in accordance with a required cooling power of each unit. System performance may benefit from accurate cooling power control. It will be understood that the primary air displacement device as described in this paragraph and further detailed in this document may but not necessarily needs to be combined with the other features as described above. Rather, it may also be provided in any other apparatus for cooling a substantially closed space.

Preferably, the primary air displacement controller is configured to derive from a secondary temperature sensor signal of the secondary temperature sensor and a desired secondary temperature a desired primary pressure difference over the primary side of the heat exchanger, and to control the primary air displacement device in dependency on the determined desired primary pressure difference and a measured primary pressure difference from a primary pressure difference sensor of the unit. A cascade control thus formed may improve system performance. Effects of local disturbances, non-linear behavior, aging etc may be corrected for by the inner loop, thereby allowing the outer loop to more consistently achieve a desired accuracy and/or behavior. A stable and reliable control may be provided.

In an embodiment, the unit comprises an adiabatic humidifier provided in the secondary inlet duct, a moisture sensor and a temperature sensor provided in the secondary outlet duct, and a moisture controller to drive the adiabatic humidifier in response to signals from the moisture sensor and the temperature sensor. By providing the adiabatic humidifier in the primary inlet duct, energy efficiency may benefit. Firstly, additional heating prior to moisturizing may be omitted, thereby saving energy. Secondly, additional cooling of the hot air in the secondary inlet duct may be provided due to the vaporization of the humidity, which will assist the cooling by the heat exchanger, hence allowing it to be operated at a lower power, thereby reducing energy consumption. It will be understood that the adiabatic humidifier as described in this paragraph and further detailed in this document may but not necessarily needs to be combined with the other features as described above. Rather, it may also be provided in any other apparatus for cooling a substantially closed space.

In an embodiment, to reduce an effect of temperature variations of the outside air, the unit comprises a first primary side damper in series in the primary inlet duct, a second primary side damper as a bypass and a primary side temperature controller configured to drive the first and second primary side dampers in opposite direction. In case of a low outside air temperature, recirculation is provided by further opening the second primary side damper and further closing the first primary side damper, so that a heated recirculation air is mixed to the outside air. Additionally, a third primary side damper may be provided in series in the primary outlet duct. It will be understood that the primary side damper as described in this paragraph and further detailed in this document may but not necessarily needs to be combined with the other features as described above. Rather, it may also be provided in any other apparatus for cooling a substantially closed space.

Preferably, in order to provide additional cooling when the outside air temperature is high, the unit further comprises a primary adiabatic humidifier, the primary side temperature controller being further configured to drive the primary adiabatic humidifier when the outside air temperature raises above a desired primary inlet air temperature. It will be understood that primary the adiabatic humidifier as described in this paragraph and further detailed in this document may but not necessarily needs to be combined with the other features as described above. Rather, it may also be provided in any other apparatus for cooling a substantially closed space.

As the apparatus comprises at least one unit for cooling, where in this document “unit” is mentioned, this should be interpreted as “at least one unit”.

All control functions and controllers as mentioned in this document may be implemented by means of suitable software instructions running to be executed by programmable devices, e.g. a programmable device comprised in each unit, such as a microcontroller per unit. Additionally or alternatively, analogue circuitry, such as amplifiers, comparators, proportional controllers proportional integrative controllers and other analogue building blocks may be comprised in the units to implement (parts of) the stated control functions.

Where in this document the term primary is used, this is to be understood so as to refer to the primary side of the unit, i.e. the side where air from the environment (outside air) is to circulate. Where in this document the term secondary is used, this is to be understood so as to refer to the secondary side of the unit, i.e. the side in connection with the space where air from the space is to circulate.

The same or similar advantages as described above with reference to the apparatus according to the invention, may also apply to the method and data center according to the invention. Also, the same or similar preferred embodiments as described with reference to the apparatus, may be provided for the method and data center according to the invention, thereby achieving same or similar effects.

### BRIEF DESCRIPTION OF THE DRAWINGS

Further embodiments, features and advantages will become clear from the appended drawing and corresponding description, in which a non-limiting embodiment is disclosed, wherein:

FIG. 1 depicts a schematic view of an apparatus according to an embodiment of the invention.

### DETAILED DESCRIPTION OF THE INVENTION

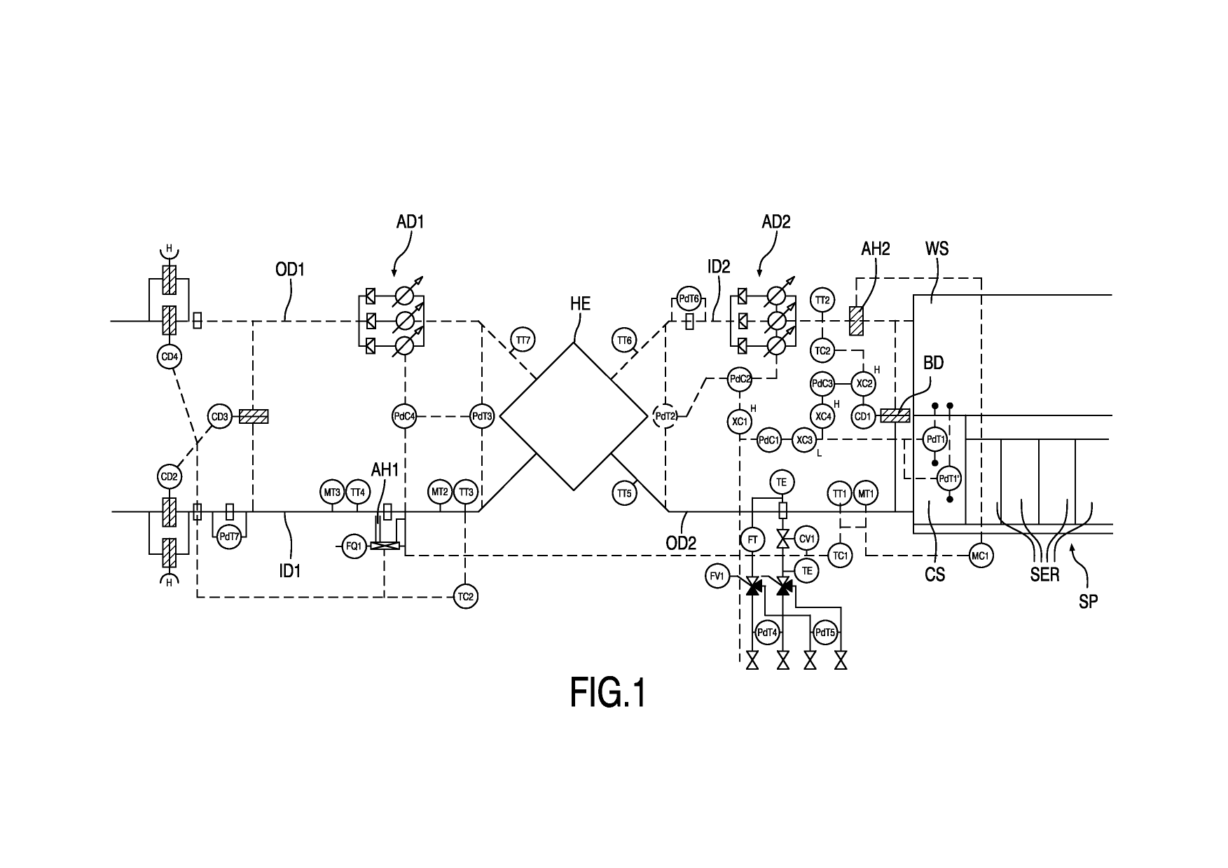

FIG. 1 depicts a schematic view of an apparatus for cooling a substantially closed space, in this embodiment a datacenter. The apparatus comprises a (cooling) unit comprising a heat exchanger HE, in this embodiment a plate heat exchanger, although other heat exchangers, such as a heat exchanger comprises a rotatable thermal wheel, may be applied alternatively. The unit comprises a first set of ducts formed by primary inlet duct ID1 and primary outlet duct OD1, both being connected to an outdoor environment. A primary air displacement device AD1, such as one or a plurality of ventilators (the FIG. 1 embodiment depicts 3 parallel ventilators), is provided in one of the primary inlet and outlet ducts. By operation of the primary air displacement device, outside air is led via the primary inlet duct, through the heat exchanger, to the primary outlet duct. Likewise, the unit comprises a second set of ducts formed by secondary inlet duct ID2 and secondary outlet duct OD2, both being connected to the substantially closed space. A secondary air displacement device AD2, such as one or more ventilators (the FIG. 1 embodiment depicts 3 parallel ventilators), is provided in one of the secondary inlet and outlet ducts. By operation of the secondary air displacement device, air from the space is led via the primary inlet duct, through the heat exchanger, to the primary outlet duct, from which the air is guided into the space again so as to form a recirculation path. In the space SP, the air is provided in this embodiment into a cold section CS, such as a corridor along a plurality of servers SER arranged in a server rack. Each server is equipped with its own air displacement device and draws air for cooling into the server according to its needs. The server and rack divide the cold section CS from a warm section WS. Heated air then flows into the warm section WS, such as in this embodiment a compartment at the ceiling side of the space, also referred to as plenum. Alternatively, any other form of hot plenum or aisle may be applied. From there, the heated air is guided via the secondary inlet duct to the heat exchanger again. Air circulated through the secondary part of the heat exchanger and the space is heated in the servers and subsequently cooled in the heat exchanger where it exchanges heat with the primary side air.

Although FIG. 1 depicts a single unit only, it is to be understood that multiple heat exchangers may be provided in parallel. Each respective secondary inlet duct in operation draws air from the space (via the plenum) and each respective secondary outlet duct in operation supplies air into the space.

In this document, the term server is to be understood so as to include any type of data processing equipment, electronic equipment, etc. The term air is to be understood so as to include any type of gas or gas mixture, including nitrogen, synthetic air, etc.

First, the secondary side of the heat exchanger will be explained in more detail.

Each unit is provided with a pressure difference sensor PdT1 which is arranged to measure a pressure difference between the corridor that supplies air to the servers and the plenum that collects the air that has been used by the servers for cooling, i.e. the pressure difference sensor measuring a pressure difference over the to be cooled devices in the space. A pressure signal from the pressure difference sensor is provided to a controller, in this example a proportional controller, PdC1, which compares the measured pressure difference with a desired pressure difference and determines a pressure control signal there from. For each unit, a corresponding pressure difference sensor and controller is provided. The pressure difference sensor may be placed so as to measure a pressure difference in between the cold section and warm section near inlet and outlet ducts of the corresponding unit, so as to take account of local pressure conditions in different parts of the space. The pressure difference sensors may for example be placed at locations where a local deviation, discontinuity, or otherwise a change in pressure may be expected, such deviation for example due to differences in air intake of neighboring servers, or, in contrast, the sensors may be placed remote from such locations. (Optionally, two or more pressure difference sensors may be provided per unit. From the measurement results by these sensors of one unit, a lowest pressure difference may be determined and provided to controller PdC1. The measured pressure difference of all sensors. The measured pressure difference of all sensors of all units may further be monitored for a maximum mutual deviation. This allows to detect locations with a high air speed where problems could occur.) The pressure control signal is provided to an air displacement device control loop which comprises pressure sensor PdT2 which measures a pressure over the secondary side of the heat exchanger and drives the secondary air displacement device. Thereby, a dual control loop configuration is provided having an inner control loop (the above mentioned air displacement control loop) and an outer control loop (comprising pressure difference sensor PdT1 and controller PdC1). The inner control loop provides for a stable operation of each air displacement device, irrespective of disturbing factors such as clogging of filters, etc. Thereto, use is made of a proportional integrating control. The pressure control signals from all pressure controllers PdC1 are provided to all units (heat exchangers plus associated air displacement devices and control). A largest of the pressure control signals is determined by maximum determination unit XC1H. The largest of the pressure control signals is provided to the secondary air displacement device. As the same is done for other units, all secondary air displacement devices will operate at a similar power level. Hence, inefficient operation conditions, whereby some of the secondary air displacement devices operate at a high power and others at a low power, may be avoided and thereby the secondary air stream substantially evenly distributed over the units. In case of failure of one of the pressure sensors, pressure controllers PdC1 or associated cabling, the signal in question is removed from the maximum determination thereby providing additional redundancy in case of a sensing failure. The pressure difference sensor PdT1 that measures the pressure difference between cold and warm section, or its pressure controller PdC1 is provided with a damping, so that sudden changes (for example in pressure) do not result in abrupt changes in the controllers thereby to prevent abrupt reaction of the air displacement devices in case of sudden changes, such as opening a door in the space, removing a server thereby leaving an opening open, etc. Any type of damping may be provided, for example a limiter that limits a rate of change. Furthermore, as the multiple pressure control signals are provided and a maximum of them is taken in each unit, sudden changes may occur. This may for example be the case when the control signal having the highest value disappears, for example because of a fault, and the second highest control signal is substantially lower. Then, a large transition would occur. Again, the maximum difference is limited so as to allow the apparatus to transit to the newly desired setting gradually.

In the embodiment disclosed here, a lowest pressure difference may result in a highest value of the control signal (as a low pressure difference requires a high secondary air displacement power to increase the pressure difference). Hence, in this embodiment, the lowest pressure difference corresponds to the highest control value, and the most demanding requirement for the air displacement device. The secondary air displacement device is hence controlled in accordance with this maximum.

Optionally, 2 or more pressure difference sensors may be provided per unit. FIG. 1 for example depicts a configuration with additional secondary pressure difference sensor PdT1′. In that case, an additional minimum determination XC3L and an additional maximum determination XC4H are provided which may otherwise both be omitted. XC3L determines a minimum of the sensor signals of the unit, hence providing to the pressure controller PdC1 a lowest of the measured values of that unit, that hence requires the highest power from the secondary air displacement device to increase pressure. On the contrary, for driving the bypass damper BD, as will be discussed below, a highest one of the measured pressure differences per unit is used, as the most urgent value per unit for the activation of the bypass damper, namely the highest pressure difference measured by the secondary pressure difference sensors of that unit, is used for the control of the bypass damper (as opening the bypass damper may be evoked by a (too) high pressure difference, as will be explained in more detail below).

A bypass air damper BD (comprising e.g. a flap or flaps) is provided so as to increase an air flow through the unit when only a low amount of air is taken by the servers. The bypass air damper connects the secondary inlet duct to the secondary outlet duct. When the pressure sensor PdT1 senses a pressure difference at or near a predetermined maximum level, a proportional control by bypass damper controller PdC3 activates the bypass air damper. A maximum determination unit XC2H is provided at its inputs with a pressure control signal (as derived from the differential pressure sensor signal) and a temperature control signal (as derived by a temperature controller TC2 from a temperature sensor signal of a secondary temperature sensor TT2 in the secondary inlet duct). A secondary bypass controller comprises a maximum determination unit XC2H and secondary damper controller CD1. The maximum determination unit determines a maximum from the pressure control signal and the temperature control signal. Hence, the bypass air damper may be controlled based on the maximum of temperature and pressure control signals so that a most relevant one of the signals, and thus a most relevant one of the temperature and pressure difference, is taken into account for determining the degree of opening of the bypass damper. The maximum as determined by XC2H is then provided to damper controller CD1 which controls the bypass damper BD. The further the bypass damper is opened, the pressure difference over the severs will decrease, and the air temperature in the inlet duct, and thus in the secondary side inlets, will decrease due to the mixing with colder air provided via the bypass damper. Thereby, the unit (in particular the air displacement device) may be kept in its desired operating range. Also, circulation through the secondary side will increase. The damper controller CD1 that controls the bypass damper BD may be activated when it is sensed in the unit that a circulation exceeds below a certain threshold. A high pressure difference over the cold/warm section) will result in a decrease of the circulation, hence a lowering of the activity of the secondary air displacement device, which translates into a low pressure difference over the secondary side of the heat exchanger HE, which is measured by heat exchanger secondary pressure difference sensor PdT2. Thus, by activating the damper controller only when a pressure difference below a pressure difference threshold is sensed over the secondary side of the heat exchanger HE, the bypass damper may open only when required. Each unit may be provided with its own bypass damper. Alternatively, a common bypass may be provided.

At the primary side of the heat exchanger, a primary side air displacement device is provided, in this example in the primary outlet duct. Outside air is guided via the inlet duct, through the primary side of the heat exchanger, where it is heated as a result of the hotter air entering the heat exchanger at the secondary side, to the primary outlet duct. The primary air displacement device is driven from a primary controller PdC4. Thereto, the primary controller PdC4 is provided with a temperature control signal, the temperature control signal being derived from temperature sensor TT1 provided in the secondary side outlet duct, which is compared to a desired temperature by corresponding temperature controller TC1. An output signal form temperature controller TC1 serves as a value expressing a desired primary side pressure difference over the primary side of the heat exchanger, which is provided to the primary controller PdC4. The primary controller further provided with a pressure difference signal from pressure difference sensor PdT3 that measures a pressure difference over the primary side of the heat exchanger (i.e. over the primary inlet and outlet duct). Thereby, the primary side air displacement device is controlled in accordance with the secondary side temperature at the outlet duct side, so as to achieve a circulation at the primary side (air pressure difference over the primary side of the heat exchanger) that matches the required cooling power to achieve the desired secondary side outlet temperature of air flowing into the space. PdC4 may be provided as a proportional integrative controller, so as to provide an accurate cooling power control. Furthermore, a control valve CV1 of a cooled water cooling is also driven from the signal from temperature controller TC1 so as to activate an additional cooled water cooling (such as a cooled water cooling coil) if desired.

As an addition, a control strategy may be provided that, on the basis of monitoring a ratio between the electrical energy consumption of the air displacement devices on the primary side and the provided cooling energy or power of the heat exchanger, will, when this ratio exceeds a certain predetermined value, shutdown the air displacement device on the primary side and will control the cooled water cooling control valves such that full required cooling power will be delivered by the cooled water cooling coil. This predetermined value may be set equal to or above the ratio between the electrical energy consumed by the apparatus that delivers the chilled water to the cooled water cooling coil (e.g. pumps, chillers, fans, all relatively to the cooling power supplied by the ensemble of these components) and the provided cooling energy or power of the cooled water cooling coil. This may be a value as a result of monitoring or a preset value. By doing so, the most energy efficient cooling apparatus in any operating condition is automatically selected, that is, when the cooled water cooling is more energy efficient than the plate heat exchanger cooling, this is automatically detected and selected. Furthermore, it is possible to include a feed forward control on the control valve for the cooled water cooling coil, on the basis of the aforementioned ratios (effectively the efficiencies of these two means of providing cooling energy or power). This will in turn allow for a balancing between these two means of providing cooling energy or power, i.e. it is possible to reduce the air displacement on the primary side (hence reducing its power consumption) in favor of increasing the delivered cooling energy via the cooled water cooling coil when this would result in an overall more energy efficient performance.

Furthermore, monitoring may be performed to detect a variety of conditions: As an example, a difference between outlet temperatures as measured by TT1 and TT2 is monitored. A value below a predetermined minimum may indicate a leak between the cold section and the warm section, which may deteriorate efficiency.

At the primary side, a range of primary air temperatures may occur due to variations in ambient, outside temperature. In order to control an inlet air temperature at the primary side the following is provided: the primary inlet air temperature is measured by temperature sensor TT3, the temperature signal being provided to temperature controller TC2. Temperature controller TC2 compares the measured temperature to a desired primary inlet air temperature. A first primary side damper CD2 is provided in series in the inlet duct, while a second primary side damper CD3 is provided as bypass. To further reduce an in stream of outside air if required, an additional third primary side damper CD4 may be provided in series in the primary outlet duct, and controlled substantially the same as primary side damper CD2. A bypass may be provided in parallel to CD2 and CD4 dampers to prevent a complete close-off in case these valves are closed. The temperature controller TC2 drives the first and second primary side dampers in opposite direction. If the outside air temperature is low, the second primary side damper is opened further so that more heated air is guided back to the inlet, while at the same time the first primary side damper is closed further, so that less outside air is led in. The temperature controller TC2 is a proportional integrative controller so as to accurately set the primary inlet temperature to the desired temperature, hence allow a controlled operation irrespective of outside air temperature. The controller TC2 further drives an adiabatic humidifier AH1 which provides for an adiabatic cooling effect. The adiabatic humidifier AH1 is operated in particular in case the outside air temperature raises above the desired primary inlet air temperature so as to provide adiabatic cooling to at least partly compensate for the higher outside air temperature. When the outside air wet bulb temperature is below the desired primary inlet air temperature the adiabatic cooling can be modulated so that it will only provide part of the available adiabatic cooling energy. As a result, the temperature on the primary inlet to the plate heat exchanger will not be below the desired primary inlet temperature to the plate heat exchanger. In a situation where a wet bulb condition of the outside air exceeds the desired primary inlet air temperature, a set point of the adiabatic cooler may be set to a higher value by e.g. adding a predetermined increment to the measured outside wet bulb condition, to improve an energy efficiency of the adiabatic cooler.

At the secondary side, a humidifier is provided also. Thereto, at the secondary outlet duct side, a temperature and humidity are measured by temperature sensor TT1 and moisture transmitter MT1 respectively. Measurement signals are provided to a proportional integrative moisture controller MC1 which drives an adiabatic humidifier AH2 provided in the secondary inlet duct. As the humidifier is provided in the secondary inlet duct of the heat exchanger, additional heating of the air before humidification may be omitted thereby reducing energy consumption. Furthermore, it is noted that the humidification provides an additional cooling effect thereby assisting in the cooling by the secondary side of the heat exchanger. A de-humidifier may also be provided, for example as a separate de-humifidication unit (not shown in FIG. 1) connected to the space so as to dehumidify the secondary side air.

Embodiments of the invention may further by defined in the form of the below clauses which form part of the description.

1. An apparatus for cooling a substantially closed space, in particular a data centre, with recirculation air, comprising at least one unit for cooling, the unit comprising a heat exchanger with a primary set of ducts and a secondary set of ducts, each set of ducts having an in- and outlet, wherein the primary in- and outlet ducts are connected to an outside environment to form a first recirculation path, and the secondary in- and outlet ducts are connected to the space to form a second recirculation path, the unit comprising a controller to control an operation thereof, and a sensor to provide a sensor signal representative of a parameter of the unit, the controller being arranged to derive a control signal from the sensor signal, whereby the unit comprises a control signal output for outputting the control signal to another unit and a control signal input for receiving a control signal from another unit, the controller being arranged to control the operation of the unit in response to the control signal and the control signal from another unit as received at the control signal input.
2. The apparatus according to clause 1, wherein the controller of the unit comprises a maximum determiner that is arranged to determine a maximum from the control signal and the control signal from another unit as received at the control signal input.
3. The apparatus according to clause 1 or 2, wherein the space is divided into a cold section and a warm section by substantially air tight dividing means, the cold section being connected to the secondary outlet duct, the warm section being connected to the secondary inlet duct, the dividing means being provided with openings at a location of a heat source, the sensor comprises a pressure difference sensor, the pressure difference sensor being configured to measure a pressure difference between the cold section and the warm section.
4. The apparatus according to clause 2 and 3, wherein the controller being configured to drive a secondary air displacement device comprised in the unit in response to a maximum of a pressure difference control signal derived from the pressure difference measured by the pressure difference sensor of the unit and at least one pressure difference control signal from at least one other unit as received at the control signal input.
5. The apparatus according to clause 4, wherein the controller comprises a dual control loop architecture, whereby an inner air displacement device control loop comprises an inner loop pressure difference sensor over the secondary ducts and an inner air displacement device controller, and the outer air displacement device control loop comprises the pressure difference sensor and an outer air displacement device controller.
6. The apparatus according to clause 5, wherein an output of the outer air displacement device controller of the unit being connected to the maximum determiner, an output of the maximum determiner being provided as a set point to the inner air displacement device controller.
7. The apparatus according to any of the preceding clauses, wherein the at least one unit comprises a secondary bypass damper to bypass the space.
8. The apparatus according to clause 7, wherein the unit comprises a secondary temperature sensor and a secondary temperature controller configured to provide a temperature control signal representative of an air temperature in the secondary inlet duct, a pressure controller to derive a pressure difference control signal from the pressure difference between cold section and the warm section as sensed by the pressure difference sensor, and a secondary bypass controller configured to control the secondary bypass damper, wherein the secondary bypass controller is configured to drive the secondary bypass damper in dependency on a highest of the temperature control signal and the pressure difference control signal.
9. The apparatus according to clause 8, wherein the secondary bypass controller is configured to allow the bypass damper to open only when a secondary side heat exchanger pressure difference sensor indicates that a pressure difference over the secondary side of the heat exchanger exceeds below a predetermined minimum pressure difference level.
10. The apparatus according to any of the preceding clauses, wherein the unit comprises a primary air displacement device arranged in one of the primary inlet duct and the primary outlet duct, a secondary temperature sensor arranged to measure a temperature of the air in the secondary outlet duct, and a primary air displacement device controller configured to control the primary air displacement device in dependency of a temperature as measured by the secondary side temperature sensor.
11. The apparatus according to clause 10, wherein the primary air displacement controller is configured to derive from a secondary temperature sensor signal of the secondary temperature sensor and a desired secondary temperature a desired primary pressure difference over the primary side of the heat exchanger, and to control the primary air displacement device in dependency on the determined desired primary pressure difference and a measured primary pressure difference from a primary pressure difference sensor of the unit.
12. The apparatus according to any of the preceding clauses, wherein the unit comprises an adiabatic humidifier provided in the secondary inlet duct, a moisture sensor and a temperature sensor provided in the secondary outlet duct, and a moisture controller to drive the adiabatic humidifier in response to signals from the moisture sensor and the temperature sensor.
13. The apparatus according to any of the preceding clauses, wherein the unit comprises a first primary side damper in series in the primary inlet duct, a second primary side damper as a bypass and a primary side temperature controller configured to drive the first and second primary side dampers in opposite direction.
14. The apparatus according to any of the preceding clauses, wherein the unit further comprises a primary adiabatic humidifier, the primary side temperature controller being further configured to drive the primary adiabatic humidifier when the outside air temperature raises above a desired primary inlet air temperature.
15. A datacenter comprising an apparatus according to any of the preceding clauses.
16. A method for cooling a substantially closed space, in particular a data centre, with recirculation air, by means of at least two cooling units, each unit comprising a heat exchanger with a primary set of ducts and a secondary set of ducts, each set of ducts having an in- and outlet, wherein the primary in- and outlet ducts are connected to an environment of the space to form a first recirculation path, and the secondary in- and outlet ducts are connected to the space to form a second recirculation path, each unit comprising a sensor to provide a sensor signal representative of a parameter of the unit, the method comprising deriving in each unit a respective control signal from the respective sensor signal of that unit and providing each unit with the control signals of each of the other units, and controlling the operation of each unit in response to the control signal of the unit and the control signal from each of the other units.
17. An apparatus for cooling a substantially closed space, in particular a data centre, with recirculation air, comprising at least one unit for cooling, the unit comprising a heat exchanger with a primary set of ducts and a secondary set of ducts, each set of ducts having an in- and outlet, wherein the primary in- and outlet ducts are connected to an outside environment to form a first recirculation path, and the secondary in- and outlet ducts are connected to the space to form a second recirculation path, the at least one unit comprises a secondary bypass damper to bypass the space.
18. The apparatus according to clause 17, wherein the unit comprises a secondary temperature sensor and a secondary temperature controller configured to provide a temperature control signal representative of an air temperature in the secondary inlet duct, a pressure controller to derive a pressure difference control signal from a pressure difference between a cold section of the space and a warm section of the space as sensed by the pressure difference sensor, and a secondary bypass controller configured to control the secondary bypass damper, wherein the secondary bypass controller is configured to drive the secondary bypass damper in dependency on a highest of the temperature control signal and the pressure difference control signal.
19. The apparatus according to clause 18, wherein the secondary bypass controller is configured to allow the bypass damper to open only when a secondary side heat exchanger pressure difference sensor indicates that a pressure difference over the secondary side of the heat exchanger exceeds below a predetermined minimum pressure difference level.
20. An apparatus for cooling a substantially closed space, in particular a data centre, with recirculation air, comprising at least one unit for cooling, the unit comprising a heat exchanger with a primary set of ducts and a secondary set of ducts, each set of ducts having an in- and outlet, wherein the primary in- and outlet ducts are connected to an outside environment to form a first recirculation path, and the secondary in- and outlet ducts are connected to the space to form a second recirculation path, wherein the unit comprises a primary air displacement device arranged in one of the primary inlet duct and the primary outlet duct, a secondary temperature sensor arranged to measure a temperature of the air in the secondary outlet duct, and a primary air displacement device controller configured to control the primary air displacement device in dependency of a temperature as measured by the secondary side temperature sensor.
21. The apparatus according to clause 20, wherein the primary air displacement controller is configured to derive from a secondary temperature sensor signal of the secondary temperature sensor and a desired secondary temperature a desired primary pressure difference over the primary side of the heat exchanger, and to control the primary air displacement device in dependency on the determined desired primary pressure difference and a measured primary pressure difference from a primary pressure difference sensor of the unit.
21. An apparatus for cooling a substantially closed space, in particular a data centre, with recirculation air, comprising at least one unit for cooling, the unit comprising a heat exchanger with a primary set of ducts and a secondary set of ducts, each set of ducts having an in- and outlet, wherein the primary in- and outlet ducts are connected to an outside environment to form a first recirculation path, and the secondary in- and outlet ducts are connected to the space to form a second recirculation path, wherein the unit comprises an adiabatic humidifier provided in the secondary inlet duct, a moisture sensor and a temperature sensor provided in the secondary outlet duct, and a moisture controller to drive the adiabatic humidifier in response to signals from the moisture sensor and the temperature sensor.
22. An apparatus for cooling a substantially closed space, in particular a data centre, with recirculation air, comprising at least one unit for cooling, the unit comprising a heat exchanger with a primary set of ducts and a secondary set of ducts, each set of ducts having an in- and outlet, wherein the primary in- and outlet ducts are connected to an outside environment to form a first recirculation path, and the secondary in- and outlet ducts are connected to the space to form a second recirculation path, wherein the unit comprises a first primary side damper in series in the primary inlet duct, a second primary side damper as a bypass and a primary side temperature controller configured to drive the first and second primary side dampers in opposite direction.
23. An apparatus for cooling a substantially closed space, in particular a data centre, with recirculation air, comprising at least one unit for cooling, the unit comprising a heat exchanger with a primary set of ducts and a secondary set of ducts, each set of ducts having an in- and outlet, wherein the primary in- and outlet ducts are connected to an outside environment to form a first recirculation path, and the secondary in- and outlet ducts are connected to the space to form a second recirculation path, wherein the unit further comprises a primary adiabatic humidifier, the primary side temperature controller being further configured to drive the primary adiabatic humidifier when the outside air temperature raises above a desired primary inlet air temperature.

1. An apparatus for cooling a substantially closed space, in particular a data centre, with recirculation air, comprising:
at least one unit for cooling, the unit comprising:
a heat exchanger with a primary set of ducts and a secondary set of ducts, each set of ducts having an in- and outlet, wherein the primary in- and outlet ducts are connected to an outside environment to form a first recirculation path, and the secondary in- and outlet ducts are connected to the space to form a second recirculation path;
a controller to control an operation thereof; and
a sensor to provide a sensor signal representative of a parameter of the unit, the controller being arranged to derive a control signal from the sensor signal;
whereby the unit further comprises a control signal output for outputting the control signal to another unit and a control signal input for receiving a control signal from another unit, the controller being arranged to control the operation of the unit in response to the control signal and the control signal from another unit as received at the control signal input.

2. The apparatus according to claim 1, wherein the controller of the unit comprises a maximum determiner that is arranged to determine a maximum from the control signal and the control signal from another unit as received at the control signal input.

3. The apparatus according to claim 1, wherein the space is divided into a cold section and a warm section by substantially air tight dividing means, the cold section being connected to the secondary outlet duct, the warm section being connected to the secondary inlet duct, the dividing means being provided with openings at a location of a heat source, the sensor comprises a pressure difference sensor, the pressure difference sensor being configured to measure a pressure difference between the cold section and the warm section.

4. The apparatus according to claim 2, wherein the controller being configured to drive a secondary air displacement device comprised in the unit in response to a maximum of a pressure difference control signal derived from the pressure difference measured by the pressure difference sensor of the unit and at least one pressure difference control signal from at least one other unit as received at the control signal input.

5. The apparatus according to claim 4, wherein the controller comprises a dual control loop architecture, whereby an inner air displacement device control loop comprises an inner loop pressure difference sensor over the secondary ducts and an inner air displacement device controller, and the outer air displacement device control loop comprises the pressure difference sensor and an outer air displacement device controller.

6. The apparatus according to claim 5, wherein an output of the outer air displacement device controller of the unit being connected to the maximum determiner, an output of the maximum determiner being provided as a set point to the inner air displacement device controller.

7. The apparatus according claim 1, wherein the at least one unit comprises a secondary bypass damper to bypass the space.

8. The apparatus according to claim 7, wherein the unit comprises a secondary temperature sensor and a secondary temperature controller configured to provide a temperature control signal representative of an air temperature in the secondary inlet duct, a pressure controller to derive a pressure difference control signal from the pressure difference between cold section and the warm section as sensed by the pressure difference sensor, and a secondary bypass controller configured to control the secondary bypass damper, wherein the secondary bypass controller is configured to drive the secondary bypass damper in dependency on a highest of the temperature control signal and the pressure difference control signal.

9. The apparatus according to claim 8, wherein the secondary bypass controller is configured to allow the bypass damper to open only when a secondary side heat exchanger pressure difference sensor indicates that a pressure difference over the secondary side of the heat exchanger exceeds below a predetermined minimum pressure difference level.

10. The apparatus according to claim 1, wherein the unit comprises a primary air displacement device arranged in one of the primary inlet duct and the primary outlet duct, a secondary temperature sensor arranged to measure a temperature of the air in the secondary outlet duct, and a primary air displacement device controller configured to control the primary air displacement device in dependency of a temperature as measured by the secondary side temperature sensor.

11. The apparatus according to claim 10, wherein the primary air displacement controller is configured to derive from a secondary temperature sensor signal of the secondary temperature sensor and a desired secondary temperature a desired primary pressure difference over the primary side of the heat exchanger, and to control the primary air displacement device in dependency on the determined desired primary pressure difference and a measured primary pressure difference from a primary pressure difference sensor of the unit.

12. The apparatus according to claim 1, wherein the unit comprises an adiabatic humidifier provided in the secondary inlet duct, a moisture sensor and a temperature sensor provided in the secondary outlet duct, and a moisture controller to drive the adiabatic humidifier in response to signals from the moisture sensor and the temperature sensor.

13. The apparatus according to claim 1, wherein the unit comprises a first primary side damper in series in the primary inlet duct, a second primary side damper as a bypass and a primary side temperature controller configured to drive the first and second primary side dampers in opposite direction.

14. The apparatus according to claim 1, wherein the unit further comprises a primary adiabatic humidifier, the primary side temperature controller being further configured to drive the primary adiabatic humidifier when the outside air temperature raises above a desired primary inlet air temperature.

15. A datacenter comprising an apparatus according to claim 1.

16. A method for cooling a substantially closed space, in particular a data centre, with recirculation air, by means of at least two cooling units, each unit comprising a heat exchanger with a primary set of ducts and a secondary set of ducts, each set of ducts having an in- and outlet, wherein the primary in- and outlet ducts are connected to an environment of the space to form a first recirculation path, and the secondary in- and outlet ducts are connected to the space to form a second recirculation path, each unit comprising a sensor to provide a sensor signal representative of a parameter of the unit, the method comprising:
deriving in each unit a respective control signal from the respective sensor signal of that unit and providing each unit with the control signals of each of the other units; and
controlling the operation of each unit in response to the control signal of the unit and the control signal from each of the other units.
